(19) United States
(12) Patent Application Publication
(10) Pub. No.: US 2026/0223312 A1
(43) Pub. Date: Jul. 30, 2026

(54) CABLE CONNECTOR ASSEMBLY HAVING CONNECTOR IDENTIFICATION MODULE

(71) Applicant: TE Connectivity Solutions GmbH, Schaffhausen (CH)

(72) Inventors: Joshua Tyler Sechrist, Fremont, CA (US); Jacobus Nicolaas Tuin, 's-Hertogenbosch (NL); Olaotan Elenitoba-Johnson, Fremont, CA (US); Sajjad Ahmed, Fremont, CA (US); Tyler Jandt, Fremont, CA (US)

(21) Appl. No.: 19/411,656

(22) Filed: Dec. 8, 2025

Related U.S. Application Data
(60) Provisional application No. 63/751,019, filed on Jan. 29, 2025.

(51) Int. Cl. H05K 7/14; H01R 12/72; H01R 12/75; H01R 13/46; H01R 13/74

(52) U.S. Cl. CPC H05K 7/1491; H01R 12/727; H01R 12/75; H01R 13/465; H01R 13/748

(57) ABSTRACT

A communication system includes a cable connector assembly having a cable connector with a cable connector housing holding cable contact assemblies each having a cable contact holder holding a first signal contact and a first shield terminated to a cable to define data channels and a cable connector identification module having first identification contacts and an identification device having unique identification data stored on the identification device. The communication system includes a circuit card connector assembly having a board connector with board contact assemblies mounted to a circuit card with second signal contacts and second shields mating with the corresponding first signal contacts and the first shields and a circuit card connector identification module for transmitting the unique identification data from the identification device to the circuit card connector assembly.

### CROSS REFERENCE TO RELATED APPLICATIONS

This application claims benefit to U.S. Provisional Application No. 63/751,019, filed 29-Jan.-2025, the subject matter of which is herein incorporated by reference in its entirety.

### BACKGROUND OF THE INVENTION

The subject matter herein relates generally to communication systems.

Cable assemblies are used to electrically connect various components within a system, such as a server or network system. The cable assemblies extend between the components, such as network, compute, storage, memory, or other components. The components may be arranged in shelves or trays of a network rack. Some systems may include components such as cards, such as line cards, daughter cards, mother boards, and the like. Each cable assembly includes multiple cables arranged in a bundle or array. Each cable forms a data channel. As the density of cable assemblies in the network system increase, it is desirable to know the locations of the components within the system, such as for service, repair or replacement.

A need remains for a method and device for identifying components and locations of components within a network system.

### BRIEF DESCRIPTION OF THE INVENTION

In one embodiment, a communication system is provided and includes a cable connector assembly that includes a cable connector and cables that extend from the cable connector. The cable connector includes a cable connector housing having walls that define a cavity. The cable connector includes cable contact assemblies received in the cavity. Each cable contact assembly includes a cable contact holder holding a first signal contact and a first shield providing shielding for the first signal contact. The first signal contacts and the first shields of the cable contact assemblies are arranged at a mating end of the cable connector. The cables are terminated to the first signal contacts and extend from a cable end of the cable connector. The cables define data channels. The cable connector assembly includes a cable connector identification module that includes first identification contacts and an identification device having unique identification data stored on the identification device. The communication system includes a circuit card connector assembly includes a circuit card and a board connector mounted to the circuit card. The board connector includes a board connector housing have walls that define a receptacle. The board connector includes board contact assemblies held by the board connector housing. The board contact assemblies include second signal contacts and second shields providing shielding for the second signal contact. The second signal contacts and the second shields are arranged at a mating end of the board connector for mating with the corresponding first signal contacts and the first shields. The second signal contacts and the second shields are terminated to the circuit card. The circuit card connector assembly includes a circuit card connector identification module includes second identification contacts configured to be mated with the first identification contacts. The first identification contacts are coupled to the second identification contacts to transmit the unique identification data from the identification device to the circuit card connector assembly.

In another embodiment, a cable connector assembly is provided and includes a cable connector that includes a cable connector housing having walls that define a cavity. The cable connector includes cable contact assemblies received in the cavity. Each cable contact assembly includes a contact holder holding a signal contact and a shield providing shielding for the signal contact. The signal contacts and the shields of the cable contact assemblies arranged at a mating end of the cable connector configured to be mated with a circuit card connector assembly. The cable connector assembly includes cables terminated to the signal contacts and extends from a cable end of the cable connector. The cables define data channels. The cable connector assembly includes a cable connector identification module configured to be mated with the circuit card connector assembly. The cable connector identification module includes identification contacts and an identification device that has unique identification data stored on the identification device. The identification device is operably coupled to the identification contacts to transmit the unique identification data to the circuit card connector assembly.

In a further embodiment, a circuit card connector assembly is provided and includes a circuit card that includes a substrate that has a mounting surface. The circuit card includes circuit contacts at the mounting surface. The circuit card connector assembly includes a board connector mounted to the circuit card at the mounting surface. The board connector includes a board connector housing that has walls to define a receptacle. The board connector includes board contact assemblies held by the board connector housing. The board contact assemblies include signal contacts and shields providing shielding for the signal contact. The signal contacts and the shields are arranged at a mating end of the board connector for mating with a cable connector assembly. The signal contacts and the shields are terminated to the circuit contacts of the circuit card. The circuit card connector assembly includes a circuit card connector identification module that includes identification contacts configured to be mated with a cable connector identification module of the cable connector assembly. The identification contacts are configured to receive unique identification data from the cable connector identification module.

### BRIEF DESCRIPTION OF THE DRAWINGS

FIG. 1 is a front view of a communication system in accordance with an exemplary embodiment.

FIG. 2 is a front view of a portion of the communication system in accordance with an exemplary embodiment.

FIG. 3 illustrates a portion of the communication system showing two of the cartridges in accordance with an exemplary embodiment.

FIG. 4 is a perspective view of a portion of the communication system showing one of the circuit card connector assemblies coupled to the corresponding cable connector assembly in accordance with an exemplary embodiment.

FIG. 5 is a top view of a portion of the communication system showing one of the circuit card connector assemblies coupled to the corresponding cable connector assembly in accordance with an exemplary embodiment.

FIG. 6 is a side view of a portion of the communication system showing one of the circuit card connector assemblies coupled to the corresponding cable connector assembly in accordance with an exemplary embodiment.

FIG. 7 is a front perspective view of a portion of the communication system showing one of the cable connector assemblies in accordance with an exemplary embodiment.

FIG. 8 is a front perspective view of one of the contact modules in accordance with an exemplary embodiment

FIG. 9 is a front perspective view of the cable connector assembly showing the cable connector identification module in accordance with an exemplary embodiment.

FIG. 10 is an enlarged view of a portion of the cable connector assembly shown in FIG. 9 showing the cable connector identification module in accordance with an exemplary embodiment.

FIG. 11 is a side perspective view of the cable connector identification module in accordance with an exemplary embodiment.

FIG. 12 is another side perspective view of the cable connector identification module in accordance with an exemplary embodiment.

FIG. 13 is a side perspective view of the cable connector identification module in accordance with an exemplary embodiment.

FIG. 14 is a partial sectional view of a portion of the communication system showing the circuit card connector assembly mated with the cable connector assembly showing the circuit card connector identification module in accordance with an exemplary embodiment.

FIG. 15 is a partial sectional, rear perspective view of the board connector housing in accordance with an exemplary embodiment.

FIG. 16 is a top view of the circuit card connector identification module in accordance with an exemplary embodiment.

FIG. 17 is a side view of the circuit card connector identification module in accordance with an exemplary embodiment.

FIG. 18 is a partial sectional view of a portion of the circuit card connector assembly showing the circuit card connector identification module partially loaded into the connector housing in accordance with an exemplary embodiment.

FIG. 19 is a partial sectional view of a portion of the circuit card connector assembly showing the circuit card connector identification module loaded into the connector housing.

FIG. 20 is a partial sectional view of a portion of the communication system showing the circuit card connector assembly mated with the cable connector assembly showing the circuit card connector identification module mated with the cable connector identification module in accordance with an exemplary embodiment.

FIG. 21 is a bottom perspective view of a portion of the circuit card connector assembly showing the circuit card connector identification module in accordance with an exemplary embodiment.

FIG. 22 is a front perspective view of a portion of the cable connector assembly in accordance with an exemplary embodiment showing one of the cable connectors.

FIG. 23 is an enlarged view of a portion of the cable connector shown in FIG. 22 in accordance with an exemplary embodiment.

FIG. 24 is a perspective view of the cable connector identification module in accordance with an exemplary embodiment.

FIG. 25 is a rear perspective view of the cable connector assembly in accordance with an exemplary embodiment showing the cable connector identification module coupled to the cable connector.

FIG. 26 is a bottom perspective view of the cable connector assembly in accordance with an exemplary embodiment showing the cable connector identification module coupled to the cable connector.

FIG. 27 is a perspective view of the cable connector assembly in accordance with an exemplary embodiment showing the cable connector identification module coupled to the cable connector.

FIG. 28 is a bottom perspective view of a portion of the cable connector showing the cable connector identification module on the connector housing in accordance with an exemplary embodiment.

### DETAILED DESCRIPTION OF THE INVENTION

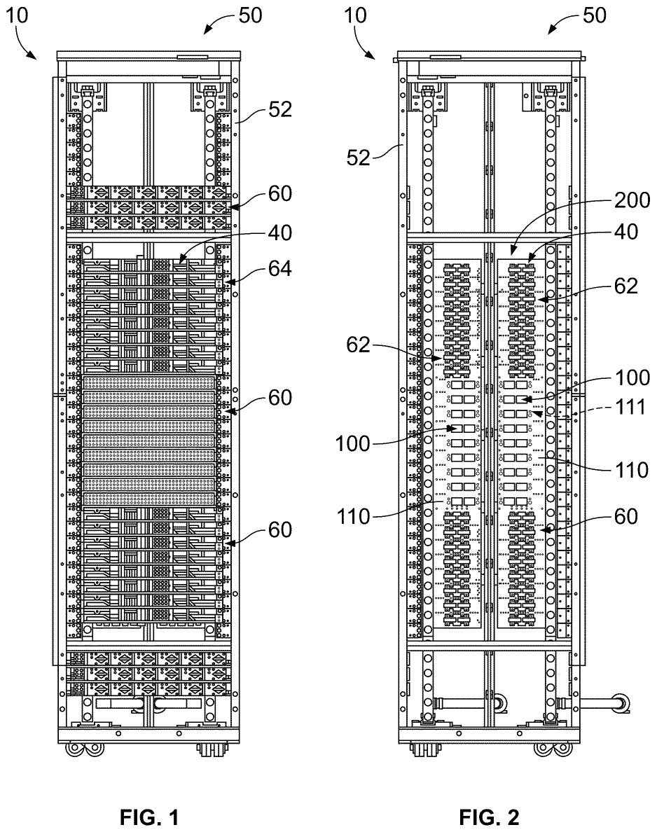

FIG. 1 is a front view of a communication system 10 in accordance with an exemplary embodiment. FIG. 2 is a front view of a portion of the communication system 10 in accordance with an exemplary embodiment. In an exemplary embodiment, the communication system 10 includes a chassis or rack 50 having a rack frame 52 holding electrical components 60. The rack 50 may be a server rack. The electrical components 60 may include fixed modules 62 (FIG. 2) and/or removable modules 64 (FIG. 1). The removable modules 64 may be mated to the fixed modules 62. For example, the removable modules 64 may be plugged into the rack frame 52 and removable from the rack frame 52. In various embodiments, the electrical components 60 may include one or more patch panels, switches, servers, routers, firewalls, and the like. The rack frame 52 may hold a power supply, cooling components, and the like.

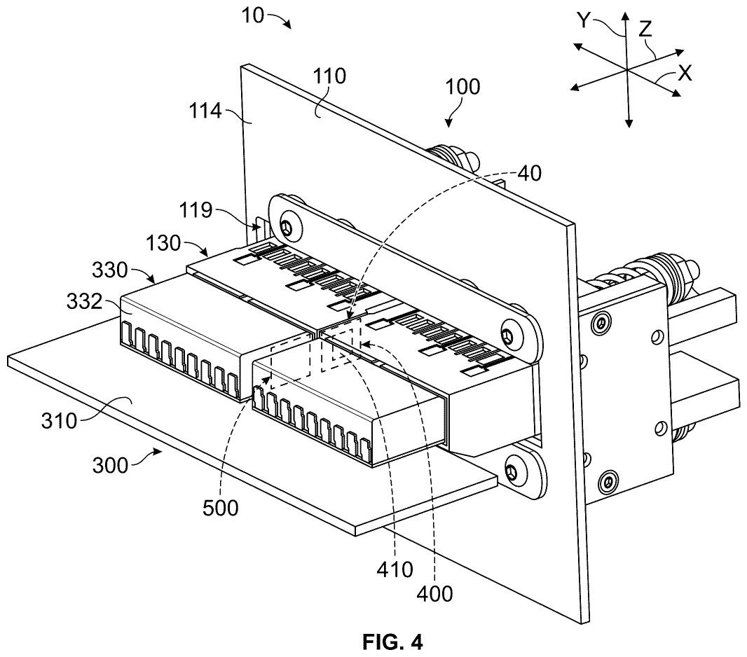

In an exemplary embodiment, the communication system 10 includes at least one cable connector assembly 100 (FIG. 2) and at least one circuit card connector assembly 300 (FIG. 4) configured to be mated with the corresponding at least one cable connector assembly 100. The cable connector assembly 100 may be part of one of the electrical components 60, such as one of the fixed modules 62. The circuit card connector assembly 300 may be part of one of the electrical components 60, such as one of the removable modules 64. In various embodiments, each circuit card connector assembly 300 may include one or more board connectors mounted to a circuit card, such as a backplane, a daughter card, a network switch, and the like.

In an exemplary embodiment, the communication system 10 includes a connector identification system 40 to identify the various cable connector assemblies 100 and/or circuit card connector assemblies 300. The connector identification system 40 may be used to identify physical locations of the cable connector assemblies 100 within the communication system 10, such as to identify which connector in a cable harness is electrically connected to which electrical component 60 for system management. In an exemplary embodiment, the connector identification system 40 may use identification devices, such as EEPROMs (Electrically Erasable and Programable Read Only Memory) or other programmable devices, chips, and the like, to hold information that allows identification of the various cable connector assemblies 100. The identification devices may be incorporated with each of the cable connector assemblies 100. For example, the identification devices may be incorporated into the cable connector assembly 100, such as housed within the connector assembly and/or the cable connector(s) and having a mating interface configured to mate with the circuit card connector assembly 300. The identification devices may have unique identification information programmed into the identification devices, such as a part number, a program name, a slot ID number, data about the associated cable connector assembly 100, and the like. In an exemplary embodiment, the identification devices also include supporting componentry like resistors, capacitors, and other supporting integrated circuits. In an exemplary embodiment, the identification devices are modular and may be incorporated into different types of cable connector assemblies 100.

In an exemplary embodiment, the communication system 10 includes a cabinet or cartridge 110 that holds the cable connector assemblies 100. The cable connector assemblies 100 include cables extending from corresponding cable connectors. The cartridge 110 may form part of the fixed modules 62. Optionally, multiple cartridges 110 may be provided (for example, left side and right side). The cartridge 110 may be coupled to the rack frame 52, such as at the rear of the rack frame 52. The cartridge 110 forms an enclosed space or chamber 111 for the cable connector assemblies 100 and the cables of the cable connector assemblies 100. The cartridge 110 is used for cable management. For example, the cables may be part of cable harnesses routed within the enclosed chamber 111 formed by the cartridge 110 electrically connecting the various cable connector assemblies 100. The cartridge 110 is used to support or position the cable connector assemblies 100 for mating with the circuit card connector assemblies 300.

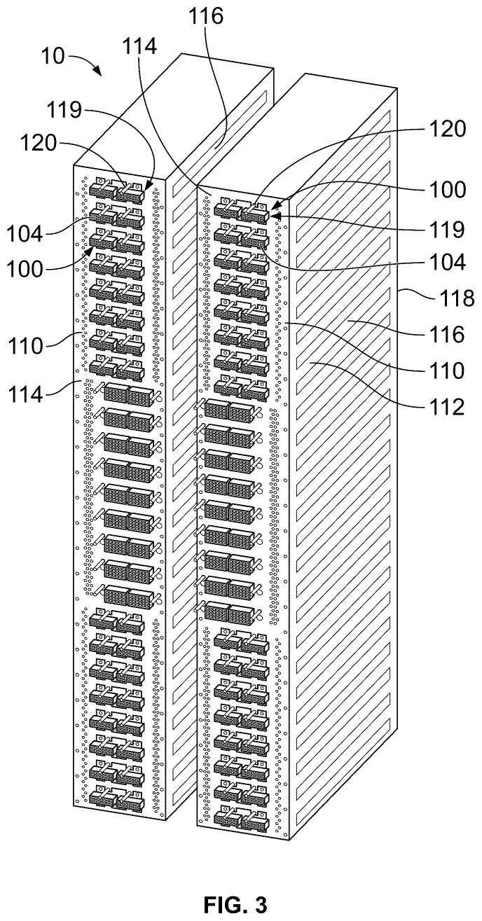

FIG. 3 illustrates a portion of the communication system 10 showing two of the cartridges 110 in accordance with an exemplary embodiment. Each cartridge 110 holds a plurality of the cable connector assemblies 100, such as in one or more rows and one or more columns. The cable connector assemblies 100 are provided at the front of the cartridge 110 for interfacing with the circuit card connector assemblies 300 (shown in FIG. 4).

In an exemplary embodiment, the cartridge 110 is formed from a plurality of panels 112, such as sheet metal panels. The cartridge 110 includes a front panel 114, side panels 116, and a rear panel 118. The panels 112 may additionally include an upper panel and/or a lower panel. The cable connector assemblies 100 are provided at the front panel 114 for mating with the circuit card connector assemblies 300. In an exemplary embodiment, the cable connector assemblies 100 are arranged in a column along the front panel 114. Optionally, the cable connector assemblies 100 may be provided in multiple columns. The mating ends of the cable connector assemblies 100 are external to the cartridge 110. For example, the cable connector assemblies 100 pass through ports or openings 119 in the front panel 114. The cable connector assemblies 100 are coupled to the front panel 114 adjacent the openings 119. In an exemplary embodiment, the cable connector assemblies 100 may float or move relative to the front panel 114 to align with and mate to the circuit card connector assemblies 300. In an exemplary embodiment, the cable connector assemblies 100 include mating guide modules 120, such as guide posts, guide blades, guide walls, guide slots, and the like, to guide mating of the cable connector assemblies 100 with the corresponding circuit card connector assemblies 300. The mating guide modules 120 extend forward of the front panel 114 to pre-align the cable connectors with the board connectors prior to mating of the cable connectors and the board connectors.

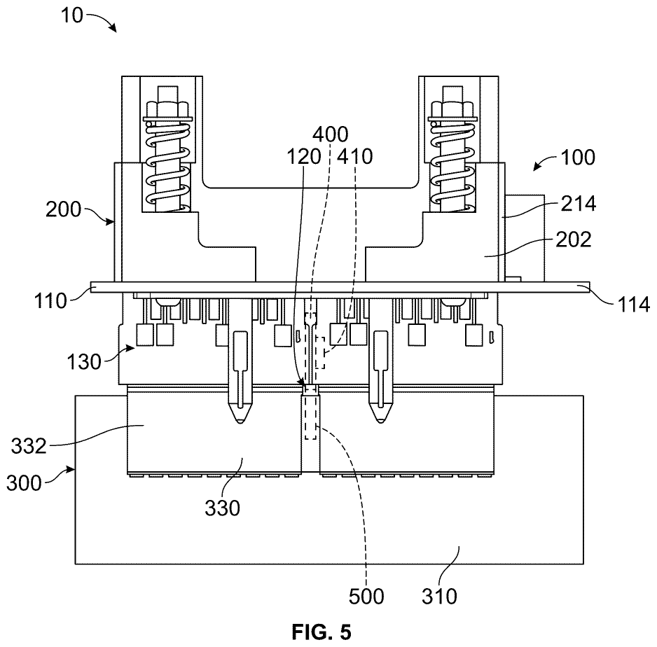

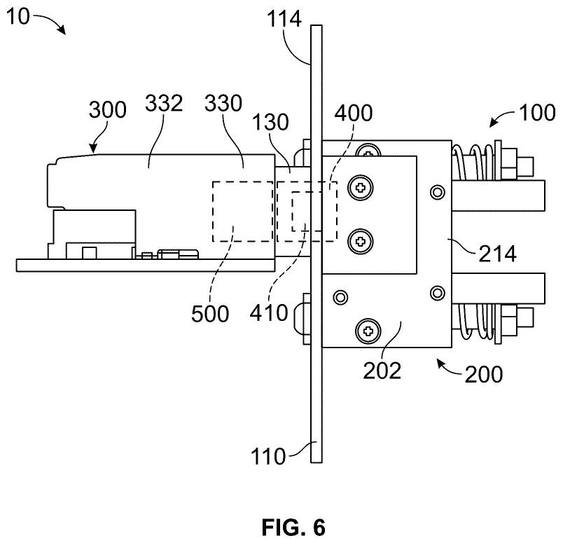

FIG. 4 is a perspective view of a portion of the communication system 10 showing one of the circuit card connector assemblies 300 coupled to the corresponding cable connector assembly 100. FIG. 5 is a top view of a portion of the communication system 10 showing one of the circuit card connector assemblies 300 coupled to the corresponding cable connector assembly 100. FIG. 6 is a side view of a portion of the communication system 10 showing one of the circuit card connector assemblies 300 coupled to the corresponding cable connector assembly 100. The cable connector assembly 100 is coupled to the cartridge 110, such as to the front panel 114. In the illustrated embodiment, the circuit card connector assembly 300 is a network component. For example, the circuit card connector assembly 300 may be a compute node, a memory module, a network switch, a storage device, a network accelerator, or another type of communication component. The circuit card connector assembly 300 may be a backplane component or a daughtercard component.

In an exemplary embodiment, the cable connector assembly 100 includes a cable connector identification module 400, forming part of the connector identification system 40. The cable connector identification module 400 is associated with the cable connector(s) of the cable connector assembly 100. The cable connector identification module 400 is used to identify the cable connector assembly 100 within the communication system 10. The cable connector identification module 400 is integrated with the other components of the cable connector assembly 100 for mating with the corresponding circuit card connector assembly 300. For example, the cable connector identification module 400 may be integrated with the cable connectors or may be located immediately adjacent or in close proximity with the cable connectors such that the cable connector identification module 400 is mated with the circuit card connector assembly 300 in unison (for example, simultaneously or near-simultaneously, such as during the same mating process) with the mating of the board connectors and the cable connectors.

In an exemplary embodiment, the cable connector identification module 400 includes an identification device 410 holding unique identification data. The identification device 410 is able to uniquely identify the cable connector assembly 100. For example, the identification device 410 is able to identify the cable connector from a plurality of cable connectors, such as within the cartridge 110. The identification device 410 may identify the location of the cable connector assembly 100 or other identifying information about the cable connector(s) or other components of the cable connector assembly 100. In an exemplary embodiment, the identification device 410 includes an EEPROM device that is programmable and configured to store unique identification data.

In an exemplary embodiment, the circuit card connector assembly 300 includes a board connector 330 mounted to a circuit card 310. The circuit card connector assembly 300 may be mounted to a front edge of the circuit card 310. The board connector 330 includes a board connector housing 332 holding signal contacts (not shown) and ground shields shielding the signal contacts. The signal contacts may be arranged in pairs. The signal contacts may be spring beams in various embodiments. The signal contacts may be pins, sockets, or other types of contacts in alternative embodiments. The signal contacts are terminated to the circuit card 310.

In an exemplary embodiment, the circuit card connector assembly 300 includes a circuit card connector identification module 500. The circuit card connector identification module 500 is electrically connected to the circuit card 310. The circuit card connector identification module 500 is configured to be mated with the cable connector identification module 400 of the cable connector assembly 100. The unique identifying data is configured to be transmitted from the cable connector identification module 400 to the circuit card connector identification module 500 when the circuit card connector assembly 300 is mated with the cable connector assembly 100. In an exemplary embodiment, the circuit card connector identification module 500 includes identification contacts (not shown) having mating ends configured to be mated to the cable connector identification module 400 and terminating ends configured to be terminated to the circuit card 310, such as by a soldered or press fit electrical connector. The mating ends may be spring beams defining a separable mating interface. The circuit card connector identification module 500 may include additional components, such as a microprocessor, an EEPROM chip, or other type of component, mounted to the circuit card 310 operably coupled to the identification contacts for controlling communication between the cable connector assembly 100 and the circuit card connector assembly 300. The circuit card connector identification module 500 may include a communication module, such as a wireless communication device, such as a transmitter or other type of wireless communication device, to transmit the data from the cable connector identification module 400 to a remote device, such as a central processing unit for the communication system 10.

The cable connector assembly 100 is received in the cartridge 110. The cable connector assembly 100 is provided at the front panel 114 for mating with the circuit card connector assembly 300 along a mating axis. In the illustrated embodiment, the mating axis extends along the Z-axis. The mating end of the cable connector 130 is configured to pass through the port or opening 119 in the front panel 114 for mating with the board connector 330. A mating end of the cable connector identification module 400 may pass through the opening 119 in the front panel 114 for mating with the circuit card connector identification module 500. The connector assemblies 100, 300 are configured to transmit and/or receive data through an interface. In an exemplary embodiment, the identification devices of the connector identification system 40 are integrated with the connector assemblies 300, 100 to mate the connector identification modules 500, 400 during mating of the connector assemblies 300, 100. For example, the cable connector identification module 400 may directly mate with the circuit card connector identification module 500 when the circuit card connector assembly 300 is mated to the cable connector assembly 100. The cable connector assemblies 100 may include plug connectors and the circuit card connector assemblies 300 may include receptacle connectors, or vice versa.

In an exemplary embodiment, the guide module 120 (for example, male guide module) is configured to be mated with a complimentary guide module (not shown, female guide module, for example, such as a slot or opening) of the circuit card connector assembly 300 to guide mating of the circuit card connector assembly 300 with the cable connector assembly 100. The guide modules may guide mating of the cable connector identification module 400 and the circuit card connector identification module 500. In various embodiments, the cable connector identification module 400 and the circuit card connector identification module 500 may be integrated into the guide modules, such as being formed or held on the male guide module and being formed in or held within the female guide module. The guide modules may be used to align the connectors in one or more lateral directions transverse to the mating axis, such as along the X-axis and/or the Y-axis. In various embodiments, the guide modules may provide both horizontal alignment (X-axis) and vertical alignment (Y-axis).

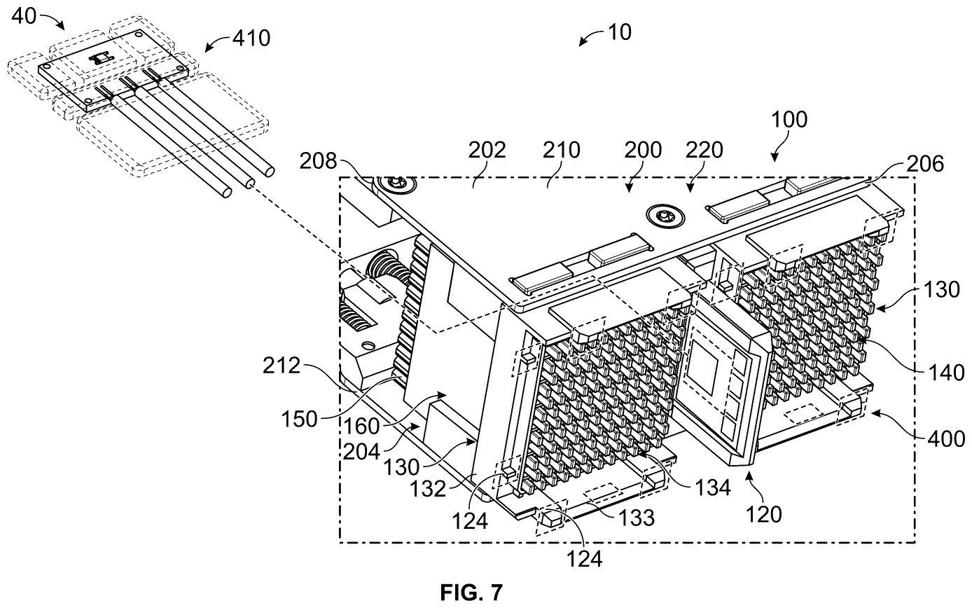

FIG. 7 is a front perspective view of a portion of the communication system 10 showing one of the cable connector assemblies 100 in accordance with an exemplary embodiment. FIG. 7 illustrates a plurality of optional locations for components, conductors, contacts, or circuits of the cable connector identification module 400 identified with bounding boxes.

The cable connector assembly 100 includes one or more cable connectors 130 and a connector holder 200 holding the cable connector(s) 130. The cable connector assembly 100 includes the cable connector identification module 400 associated with the cable connector(s) 130. The cable connector identification module 400 is part of the connector identification system 40 used to identify the cable connector assembly 100 within the system. The cable connector identification module 400 may be integrated with the cable connector(s) 130 in the connector holder 200. The cable connector identification module 400 is configured to be mated to the circuit card connector assembly 300 with the cable connector 130.

In an exemplary embodiment, the cable connector identification module 400 includes an identification device 410 (shown schematically in FIG. 7) holding unique identification data. The identification device 410 may be located at one of the optional locations identified with bounding boxes or located remote therefrom and electrically connected using wires, cables, circuits, contacts or other conductors, to the mating interface. The identification device 410 is able to uniquely identify the cable connector 130. For example, the identification device 410 is able to identify the cable connector 130 from a plurality of cable connectors, such as within the cartridge 110. The identification device 410 may identify the location of the cable connector 130 or other identifying information about the cable connector 130. In an exemplary embodiment, the identification device 410 is an EEPROM device that is programmable and configured to store unique identification data.

In the illustrated embodiment, the cable connector assembly 100 includes two cable connectors 130 arranged or stacked generally side-by-side. Greater or fewer cable connectors 130 may be provided in alternative embodiments. The cable connectors 130 may be vertically stacked rather than horizontally stacked in alternative embodiments. The mating ends of the cable connectors 130 pass through the opening 119 in the front panel 114 for mating with the board connector 330 (FIG. 4). In the illustrated embodiment, the guide module 120 is located between the cable connectors 130. The guide module 120 may additionally or alternatively be located at other locations, such as flanking on the outsides or located above and/or below the cable connectors 130.

The cable connector 130 includes a connector housing 132 holding a plurality of communication contact modules 160 configured to transmit data, such as high speed data signals. The contact modules 160 include contact assemblies 140 configured to be mated with the circuit card connector assembly 300. The contact assemblies 140 are terminated to ends of cables 150 extending from the cable connector 130. For example, the cables 150 may extend from the rear ends of the contact modules 160. The contact assemblies 140 are arranged together within the contact modules 160. For example, the contact modules 160 hold the contact assemblies 140 in columns. A plurality of the contact modules 160 are received in the connector housing 132, such as being arranged in a contact module stack.

The connector housing 132 includes walls 133 forming a cavity 134 that receives the contact modules 160. The contact assemblies 140 are arranged in the cavity 134 at a mating end for mating with the board connector 330. For example, the contact assemblies 140 are arranged in the cavity 134 in rows and columns. The cavity 134 may form a receptacle that receives the mating end of the board connector 330. In an exemplary embodiment, the connector housing 132 includes a plurality of module slots in the cavity 134. Each module slot receives one of the contact modules 160. The contact modules 160 may be latchably coupled to the connector housing 132 in the corresponding module slots.

The connector housing 132 defines a mating end configured to be mated with the board connector 330. For example, the mating end may be plugged into a receptacle of the board connector 330 and/or a portion of the connector housing 132 may define a receptacle that receives a portion of the board connector 330. The walls of the connector housing 132 may be chamfered and have lead-in surfaces to guide mating of the board connector 330 in the cavity 134. The lead-in surfaces and/or walls of the connector housing 132 may form a guide module for the cable connector assembly 100. The connector housing 132 may have guide features to properly position the board connector 330 within the cavity 134 and/or to properly position a plug portion at the mating end of the connector housing 132 in the board connector 330. The connector housing 132 may include guide lugs or guide rails 124 at the mating interface to guide mating and/or for keyed mating with the board connector 330. The guide rails 124 may form surfaces for locating components of the cable connector identification module 400. For example, the circuits, contacts, or conductors of the cable connector identification module 400 may be located along the top surfaces, bottom surfaces, side surfaces, and the like of the guide rails 124.

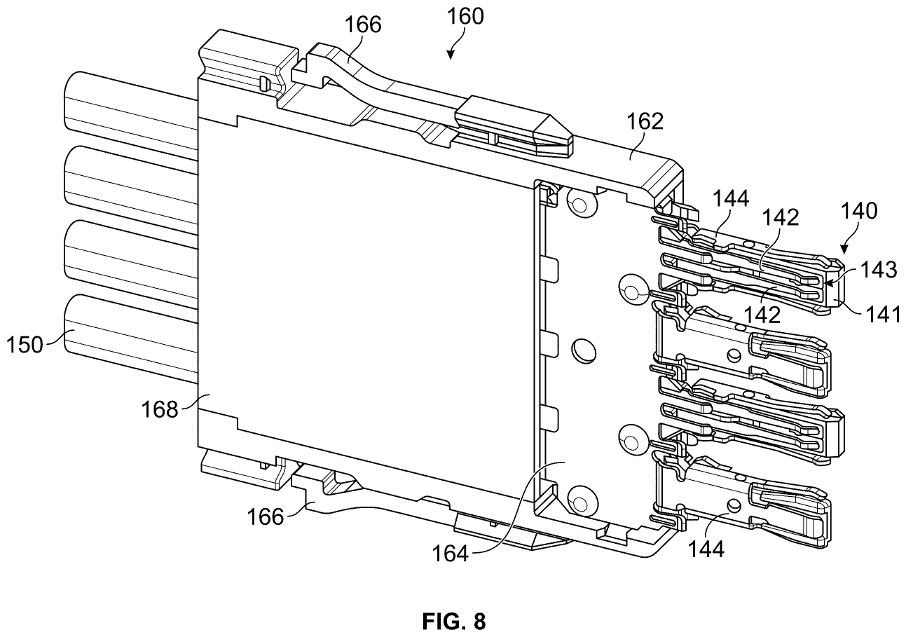

With additional reference to FIG. 8, which is a front perspective view of one of the contact modules 160 in accordance with an exemplary embodiment, the contact module 160 includes a structure holding the contact assemblies 140 and the cables 150. For example, the contact module 160 includes a body 162 holding the contact assemblies 140 and the cables 150. The cables 150 extend from a cable end of the contact module 160. The contact assemblies 140 extend from a mating end of the contact module 160.

The body 162 may be generally rectangular having a top, a bottom, a front, a rear, a first side and a second side. The sides may be generally planar and parallel to each other configured to be stacked in the module stack side-by-side with the other contact modules 160. In an exemplary embodiment, the body 162 holds a ground shield 164. The body 162 includes latches 166, such as at the top and the bottom of the body 162, used to secure the contact module 160 in the connector housing 132 (FIG. 5). The contact module 160 may include a strain relief 168, such as at the cable end, configured to hold the ends of the cables 150 and provide strain relief for the cables 150. The strain relief 168 may be an overmold overmolded over the ends of the cables 150.

Each contact assembly 140 includes at least one signal contact 142, a contact holder 141 holding the at least one signal contact 142, and a shield 144 coupled to the contact holder 141 and providing electrical shielding for the at least one signal contact 142. Optionally, multiple contact assemblies 140 may be integrated into a common structure. For example, the contact holders 141 of each of the contact assemblies 140 may be a unitary structure, such as being a single molded piece holding all of the signal contacts 142 and the shields 144.

In the illustrated embodiment, each contact assembly 140 includes a pair of the signal contacts 142, which define a differential pair. In various embodiments, the signal contacts 142 may be deflectable spring beams. However, in alternative embodiments, the signal contacts 142 may be pin contacts, socket contacts, or other types of contacts. The signal contacts 142 may be stamped and formed contacts. Each signal contact 142 is configured to be electrically connected to a corresponding wire or conductor of the cable 150. In an exemplary embodiment, the cable 150 is a twin-axial cable having a first conductor and a second conductor terminated to corresponding signal contacts 142.

The contact holder 141 is manufactured from a dielectric material, such as a plastic material. The contact holder 141 may be a molded part. The contact holder 141 includes a contact channel 143 for each signal contact 142. In the illustrated embodiment, the contact holder 141 has two contact channels 143 for the pair of signal contacts 142. In various embodiments, the contact holder 141 is preformed and the signal contacts 142 are loaded into the contact holder 141. In other various embodiments, the contact holder 141 is formed in situ around the signal contacts 142, such as being overmolded over the signal contacts 142. The cable 150 may extend into an end of the contact holder 141 to terminate to the signal contacts 142. The contact holder 141 may provide strain relief for the end of the cable 150. In other embodiments, a single contact holder may be provided for the contact module 160 configured to hold each of the pairs of the signal contacts 142, such as four pairs of the signal contacts 142 in a single molded part.

The shield 144 may be a stamped and formed shield. The shield 144 is configured to be coupled to the contact holder 141. Optionally, shields may be provided at both sides of the contact module 160. The shield 144 may provide shielding on multiple sides of the signal contacts 142. In an exemplary embodiment, the front end of the shield 144 is C-shaped providing electrical shielding on three sides of the pair of signal contacts 142. The shield 144 may have other shapes in alternative embodiments. The shield 144 may have deflectable spring beams configured to be mated to a shield structure of the circuit card connector assembly 300. The shield 144 may be configured to be electrically connected to the cable shield of the cable.

With reference back to FIG. 7, the connector holder 200 is used to hold the cable connector(s) 130 and the cable connector identification module 400 relative to the front panel 114. The connector holder 200 is configured to be coupled to the cartridge 110 to position each cable connector 130 and the cable connector identification module 400 relative to the cartridge 110. In an exemplary embodiment, the cable connector 130 is movable relative to the connector holder 200 to position the cable connector 130 during mating with the board connector 330. For example, the connector holder 200, and thus the cable connector 130 and the cable connector identification module 400, may be movable along the mating axis (along the Z-axis) to accommodate overtravel of the circuit card connector assembly 300 during mating. In various embodiments, the connector holder 200, and thus the cable connector 130 and the cable connector identification module 400, may have a limited amount of floating movement relative to the front panel 114 to accommodate misalignment of the cable connector 130 relative to the board connector 330. For example, the connector holder 200 may be movable relative to the front panel 114 along the X-axis and/or along the Y-axis to accommodate misalignment of the cable connector 130 relative to the board connector 330.

The connector holder 200 includes a frame 202 defining a connector chamber 204. The cable connector(s) 130 are received in the connector chamber 204. The frame 202 supports the cable connector 130 in the connector chamber 204. The cable connector identification module 400 may be coupled to the frame 202. For example, the cable connector identification module 400 may be provided on one or more of the cable connectors 130 or may be provided on the guide module 120, which are mounted to the frame 202. In other various embodiments, a portion of the cable connector identification module 400 may be mounted to the frame 202 separate from the cable connectors 130 and/or separate from the guide module 120. For example, an EEPROM dongle may be mounted to the frame 202 separate from the cable connectors 130. In various embodiments, the cable connector identification module 400 located in the connector chamber 204. In other various embodiments, the cable connector identification module 400 may be mounted to an exterior of the frame 202, such as to a side of the frame 202. The cable connector identification module 400 may be coupled to the frame 202 in alignment with the cable connectors 130, such as in line with (for example, coplanar) the cable connectors 130. The cable connector identification module 400 may be arranged side-by-side with the cable connector 130. A portion of the cable connector identification module 400 may extend forward of the cable connectors 130 for mating with the circuit card connector assembly 300.

The frame 202 extends between a front 206 and a rear 208 of the connector holder 200. The mating ends of each cable connector 130 is provided at or forward of the front 206 of the connector holder 200 for mating with the board connector 330. The mating end of the cable connector identification module 400 is provided at or forward of the front 206 of the connector holder 200 for mating with the circuit card connector identification module 500. The cables 150 extends from the rear 208 of the connector holder 200. The guide module 120 extends forward from the front 206.

In an exemplary embodiment, the frame 202 includes an upper frame member 210, a lower frame member 212, a first side frame member 214, and a second side frame member 216. The connector chamber 204 is defined between the upper frame member 210 and the lower frame member 212. The connector chamber 204 is defined between the first and second side frame members 214, 216. In an exemplary embodiment, the cable connectors 130 are supported by one or more of the frame members. The cable connector identification module 400 may be supported by one or more of the frame members.

The upper frame member 210, the lower frame member 212, the first side frame member 214, and/or the second side frame member 216 may be plates or blocks. For example, the upper frame member 210, the lower frame member 212, the first side frame member 214, and/or the second side frame member 216 may be stamped and formed plates. The upper frame member 210, the lower frame member 212, the first side frame member 214, and/or the second side frame member 216 may be die cast or molded blocks. In an exemplary embodiment, the upper frame member 210, the lower frame member 212, the first side frame member 214, and/or the second side frame member 216 may be discrete pieces secured together using fasteners, clips, latches, welding or other securing means. In other various embodiments, the upper frame member 210, the lower frame member 212, the first side frame member 214, and/or the second side frame member 216 may be integral with each other. The upper frame member 210, the lower frame member 212, the first side frame member 214, and the second side frame member 216 form a brick 220 used to hold the cable connectors 130 and the cable connector identification module 400. The brick 220 is a rectangular structure that surrounds the connector chamber 204. The brick 220 is configured to be coupled to the cartridge 110 to hold the cable connectors 130 and the cable connector identification module 400 relative to the cartridge 110.

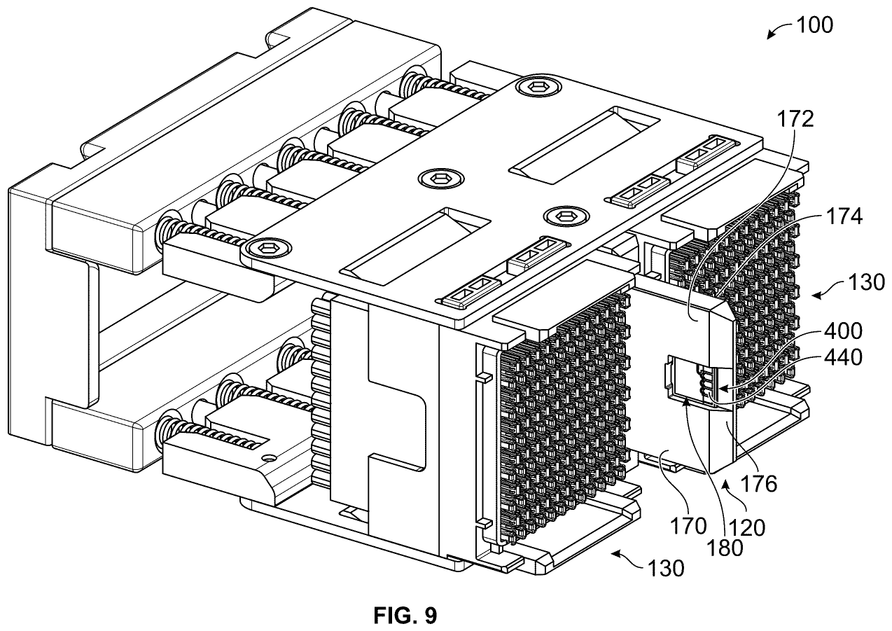

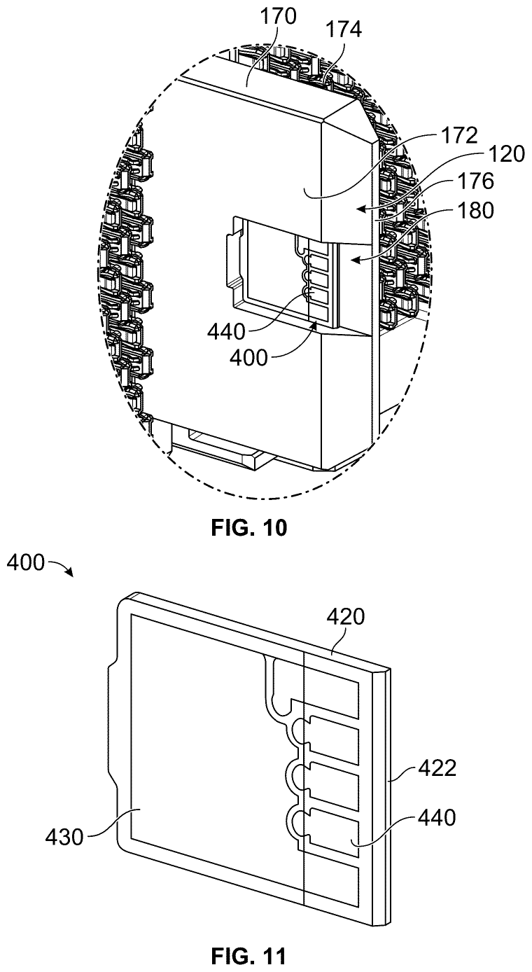

FIG. 9 is a front perspective view of the cable connector assembly 100 showing the cable connector identification module 400 in accordance with an exemplary embodiment. FIG. 10 is an enlarged view of a portion of the cable connector assembly 100 shown in FIG. 9 showing the cable connector identification module 400 in accordance with an exemplary embodiment.

In the illustrated embodiment, the cable connector identification module 400 is integrated into the guide module 120. As such, the cable connector identification module 400 does not occupy any additional space or real estate within the cable connector assembly 100 and does not require the cable connector assembly 100 to dimensionally expand either vertically or horizontally. Additionally, the cable connector identification module 400 does not use any of the data channels of the cable connector 130 to transmit the identification data, thus allowing all of the data channels for high speed data communication between the cable connector 130 and the corresponding board connector 330. In various embodiments, the cable connector identification module 400 may be retrofit into existing cable connector assemblies or cartridges with only slight modification, such as switching out the guide module thereof with the replacement guide module 120 incorporating the cable connector identification module 400.

In an exemplary embodiment, the guide module 120 includes a guide blade 170. The guide blade 170 may be a composite plastic material. For example, the guide blade 170 may be a molded body. The guide blade 170 has a generally rectangular cross-section. In the illustrated embodiment, the guide blade 170 is oriented vertically and located between the pair of cable connectors 130. The guide blade 170 has a first surface 172 at a right side and a second surface 174 at a left side. The first and second surfaces 172, 174 may be generally planar and parallel to each other on opposite sides of the guide blade 170. The guide blade 170 has a leading edge 176 at the front of the guide blade 170. The leading edge 176 is chamfered to provide mating guidance. For example, the leading edge 176 is narrower and/or shorter to fit in a guide slot and located the guide blade 170 in the guide slot to gather the connector assemblies during mating and ensure proper positioning of the cable connector assembly 100 with the circuit card connector assembly 300. The guide blade 170 properly aligns the cable connectors 130 with the board connectors 330 prior to mating of the connectors and the contacts of the connectors.

In an exemplary embodiment, the guide blade 170 includes a pocket 180 in the first surface 172. The cable connector identification module 400 is located in the pocket 180. For example, the cable connector identification module 400 may be loaded into the pocket 180. In other various embodiments, the guide blade 170 may be formed around the cable connector identification module 400, such as being overmolded around the cable connector identification module 400. A portion of the cable connector identification module 400 is exposed in the pocket 180 for mating with the circuit card connector identification module 500. For example, identification contacts 440 of the cable connector identification module 400 may be exposed within the pocket 180 for mating with the circuit card connector identification module 500.

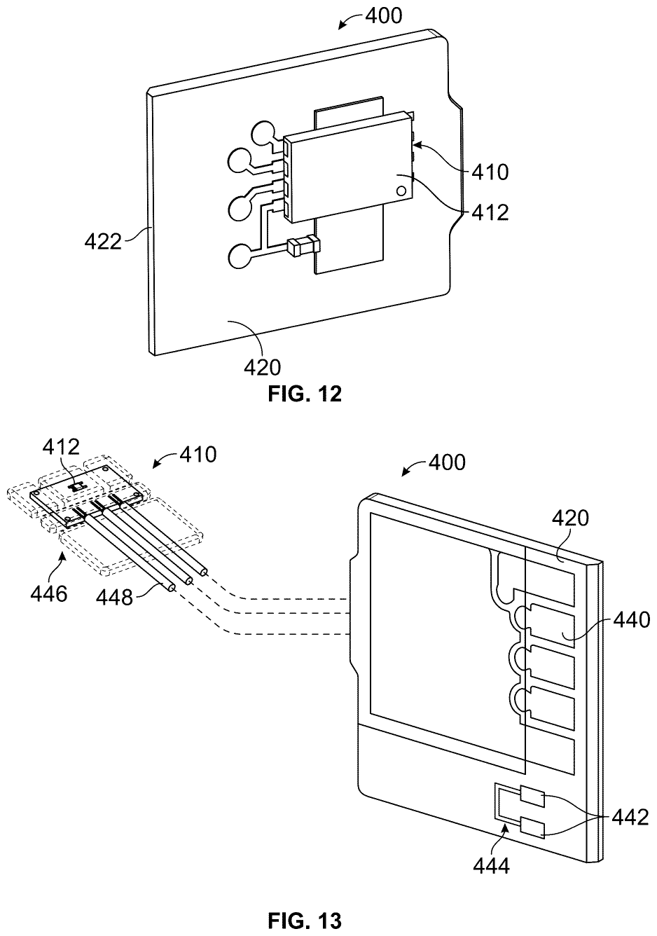

FIG. 11 is a side perspective view of the cable connector identification module 400 in accordance with an exemplary embodiment. FIG. 12 is another side perspective view of the cable connector identification module 400 in accordance with an exemplary embodiment.

In an exemplary embodiment, the cable connector identification module 400 includes the identification device 410 and identification contacts 440 operably coupled to the identification device 410. The identification contacts 440 may be signal contacts, power contacts, ground contacts, loopback contacts, proximity contacts, or other types of contacts. The identification contacts 440 may have staggered or offset mating interfaces, such as to allow sequential mating/breaking. For example, ground contacts may be located closest to the mating edge to allow first mate/last break. The loopback or proximity contacts may be located furthest from the mating edge to allow last mate/first break to provide indication of full mating of the connectors, such as to control on/off of the data and/or power transmissions. The identification contacts 440 are configured to be mated with the circuit card connector identification module 500 to electrically connect the cable connector identification module 400 and the circuit card connector identification module 500.

In an exemplary embodiment, the identification device 410 includes an electronic device 412 that stores unique identification data. The electronic device 412 may be an integrated circuit, such as a chip. In an exemplary embodiment, the electronic device 412 is an EEPROM device, such as an EEPROM chip or component. The electronic device 412 is programmable to store the identification data, such as a part number, a program name, a slot ID number, and the like. The electronic device 412 may be a surface mount component, such as having solder tails, solder pads, solder balls, or other conductors or leads for connection to another component, such as a circuit board or directly to the identification contacts 440.

In an exemplary embodiment, the identification device 410 includes a printed circuit board 420 hosting the electronic device 412 and the identification contacts 440, and may include other components mounted to the printed circuit board 420, such as capacitors, resistors, a processor, a memory module, or another component. The electronic device 412 is mounted to the printed circuit board 420. For example, the electronic device 412 may be soldered to the printed circuit board 420. In alternative embodiments, the electronic device 412 may be remote from the printed circuit board 420, such as being included on a dongle that is connected to the printed circuit board 420 by one or more cables, wires, flex circuits and the like.

In an exemplary embodiment, the printed circuit board 420 includes circuits, such as pads, traces, vias, and the like. The circuits may define the identification contacts 440. In alternative embodiments, the identification contacts 440 may be separate contacts, such as stamped and formed contacts, terminated to the printed circuit board 420 and extending from the printed circuit board 420 for mating with the circuit card connector identification module 500. In the illustrated embodiment, the identification contacts 440 are pads of the printed circuit board 420 arranged at a card edge 422 of the printed circuit board 420. The card edge 422 is provided at a mating end of the identification device 410 for mating with the circuit card connector identification module 500.

In various embodiments, the identification device 410 includes a device shell or cover 430 holding or covering the printed circuit board 420 and the electronic device 412. The device shell 430 surrounds portions of the printed circuit board 420 and the electronic device 412 to protect the components. The device shell 430 may be an overmold body overmolded over the printed circuit board 420 and the electronic device 412. The device shell 430 may be a composite plastic material. The card edge 422 may protrude from the device shell 430 for mating with the circuit card connector identification module 500.

FIG. 13 is a side perspective view of the cable connector identification module 400 in accordance with an exemplary embodiment. In the illustrated embodiment, the cable connector identification module 400 includes loopback contacts 442 forming a loopback circuit 444. In the illustrated embodiment, the identification device 410 is a remote identification device 446, such as a dongle, connected to the printed circuit board 420 via cables 448. The electronic device 412 is part of the remote identification device 446.

The loopback contacts 442 are configured to be coupled to corresponding loopback contacts of the circuit card connector identification module 500. The loopback circuit 444 provides indication to the connector identification system 40 that the connectors are properly mated. The feedback provided by the loopback circuit 444 may control operation of the system, such as to power up or power down and/or to transmit signals based on the loopback circuit 444 being closed or open. In an exemplary embodiment, the loopback contacts 442 are offset relative to the other identification contacts 440, such as further from the mating edge to allow last mate/first break to provide indication of full mating of the connectors, such as to control on/off of the data and/or power transmissions.

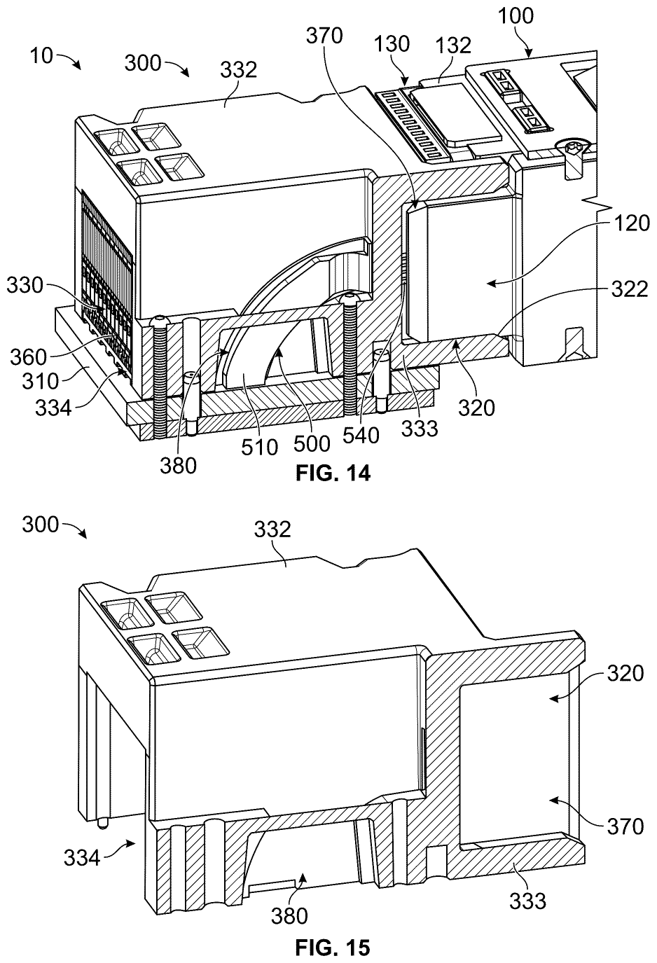

FIG. 14 is a partial sectional view of a portion of the communication system 10 showing the circuit card connector assembly 300 mated with the cable connector assembly 100 showing the circuit card connector identification module 500 in accordance with an exemplary embodiment. FIG. 14 shows the cable guide module 120 mated with a circuit card guide module 320. The guide modules 120, 320 are used to guide mating of the circuit card connector assembly 300 with the cable connector assembly 100. In an exemplary embodiment, the circuit card connector identification module 500 and the cable connector identification module 400 are integrated with the guide modules 120, 320. For example, the circuit card connector identification module 500 and the cable connector identification module 400 are located outside of the mating interfaces of the cable connectors 130 and the board connectors 330 so as to not increase the size of the connector assemblies 100, 300 and/or so as to not utilize or occupy any data channels of the cable connectors 130 and the board connectors 330, which are used for high speed data transmission within the communication system 10.

The circuit card connector assembly 300 includes the board connector(s) 330 mounted to the circuit card 310. For example, the board connector housing 332 of the board connector 330 is mounted to the circuit card 310, such as using fasteners. The board connector 330 includes a plurality of communication contact modules 360 held by the board connector housing 332 and configured to transmit data, such as high speed data signals. For example, the communication contact modules 360 may be arranged in a cavity in the board connector housing 332 in a contact module stack. The contact modules 360 include signal contacts and ground contacts and/or ground shields configured to be mated with the cable connector 130 and configured to be terminated to the circuit card 310.

The connector housing 332 defines a mating end configured to be mated with the cable connector 130. For example, the mating end may be plugged into a receptacle of the cable connector 130 and/or a portion of the connector housing 332 may define a receptacle that receives a portion of the cable connector 130.

With additional reference to FIG. 15, which is a partial sectional, rear perspective view of the board connector housing 332, the connector housing 332 includes walls 333 forming a cavity 334 that receives the contact modules 360 (FIG. 14). The cavity 334 may form a receptacle that receives the mating end of the cable connector 130. In an exemplary embodiment, the connector housing 332 includes the circuit card guide module 320. For example, the walls 333 may form a guide slot 370 that receives the guide blade 170. The guide slot 370 may be rectangular. However, the guide slot 370 may have other shapes corresponding to the shape of the guide blade 170. The guide slot 370 is open at the mating end of the connector housing 332 to receive the guide blade 170.

In an exemplary embodiment, the circuit card connector identification module 500 is received in the guide slot 370 to mate with the cable connector identification module 400. In an exemplary embodiment, the circuit card connector identification module 500 includes a contact holder 510 holding identification contacts 540. The contact holder 510 is coupled to the connector housing 332 to position the identification contacts 540, such as for mating with the cable connector identification module 400 and for connection to the circuit card 310. For example, the contact holder 510 may be received in a pocket 380 in the connector housing 332. The contact holder 510 may extend from the guide slot 370 at the front of the connector housing 332 to the circuit card 310 at the bottom of the connector housing 332. The contact holder 510 may be an overmold body overmolded over the identification contacts 540.

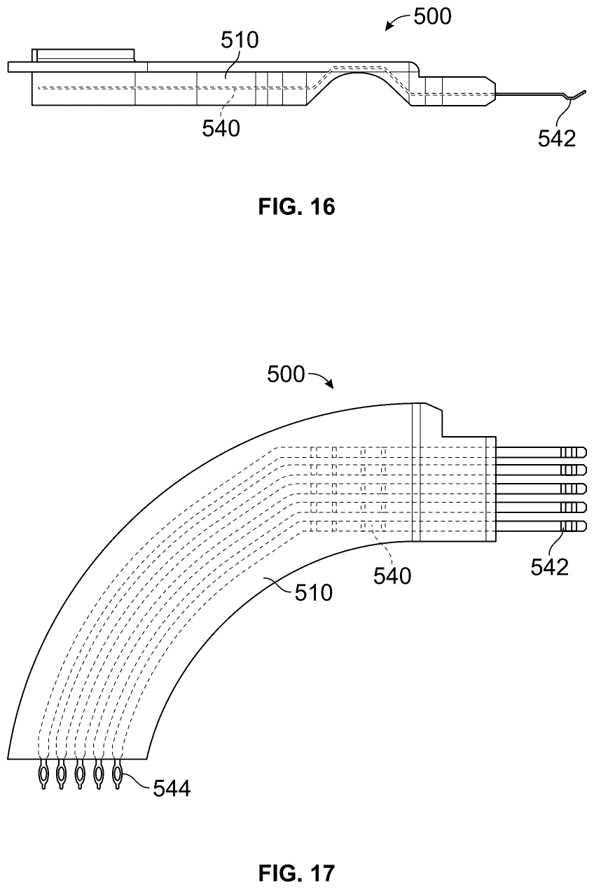

FIG. 16 is a top view of the circuit card connector identification module 500 in accordance with an exemplary embodiment. FIG. 17 is a side view of the circuit card connector identification module 500 in accordance with an exemplary embodiment. The circuit card connector identification module 500 includes the contact holder 510 and the identification contacts 540.

In an exemplary embodiment, the identification contacts 540 are stamped and formed contacts. For example, the identification contacts 540 may be stamped as part of a leadframe and the contact holder 510 may be overmolded over the leadframe. In the illustrated embodiment, the circuit card connector identification module 500 includes five identification contacts 540. Greater or fewer identification contacts 540 may be provided in alternative embodiments. The identification contacts 540 may be signal contacts, ground contacts, power contacts, loopback contacts, proximity contacts, or other types of contacts.

Each identification contact 540 extends between a mating end 542 and a terminating end 544. The terminating end 544 is configured to be terminated to the circuit card 310. In the illustrated embodiment, the terminating ends 544 are compliant pins configured to be press fit into the circuit card 310. The terminating ends 544 may be solder tails in alternative embodiments. The mating end 542 is configured to be mated to the corresponding identification contact 440 of the cable connector identification module 400 at a separable mating interface. In the illustrated embodiment, the mating ends 542 are spring beams, such as deflectable spring beams, configured to interface with the identification contacts 440.

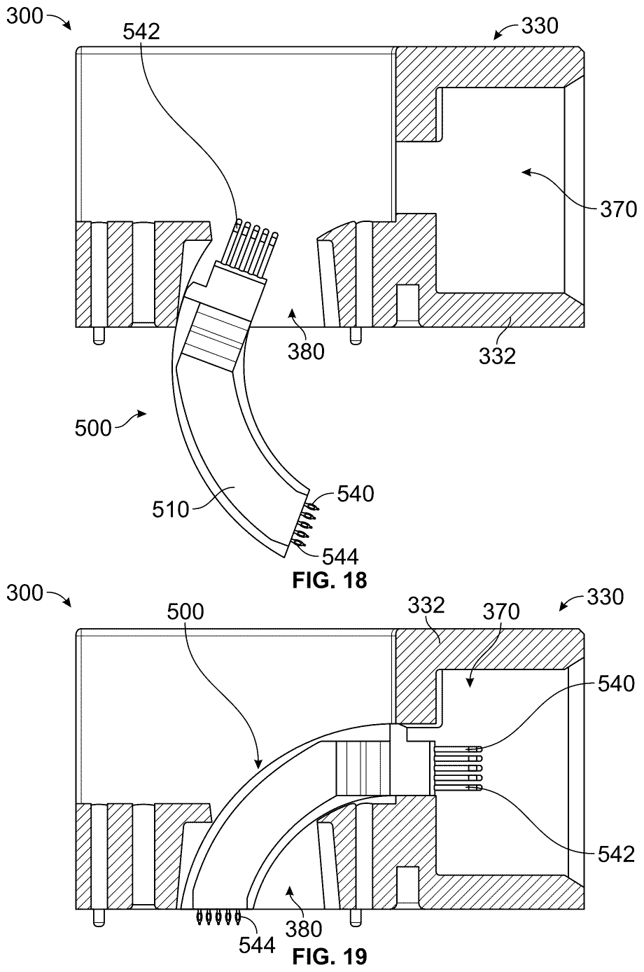

FIG. 18 is a partial sectional view of a portion of the circuit card connector assembly 300 showing the circuit card connector identification module 500 partially loaded into the connector housing 332. FIG. 19 is a partial sectional view of a portion of the circuit card connector assembly 300 showing the circuit card connector identification module 500 loaded into the connector housing 332.

During assembly, the circuit card connector identification module 500 is loaded into the pocket 380 and coupled to the connector housing 332. The front end of the circuit card connector identification module 500 is received in the guide slot 370 such that the mating ends 542 of the identification contacts 540 are positioned for mating with the cable connector identification module 400. When assembled, the terminating ends 544 of the identification contacts 540 are arranged for termination to the circuit card 310. For example, the terminating ends 544 extend from the bottom of the connector housing 332 for connection to the circuit card 310.

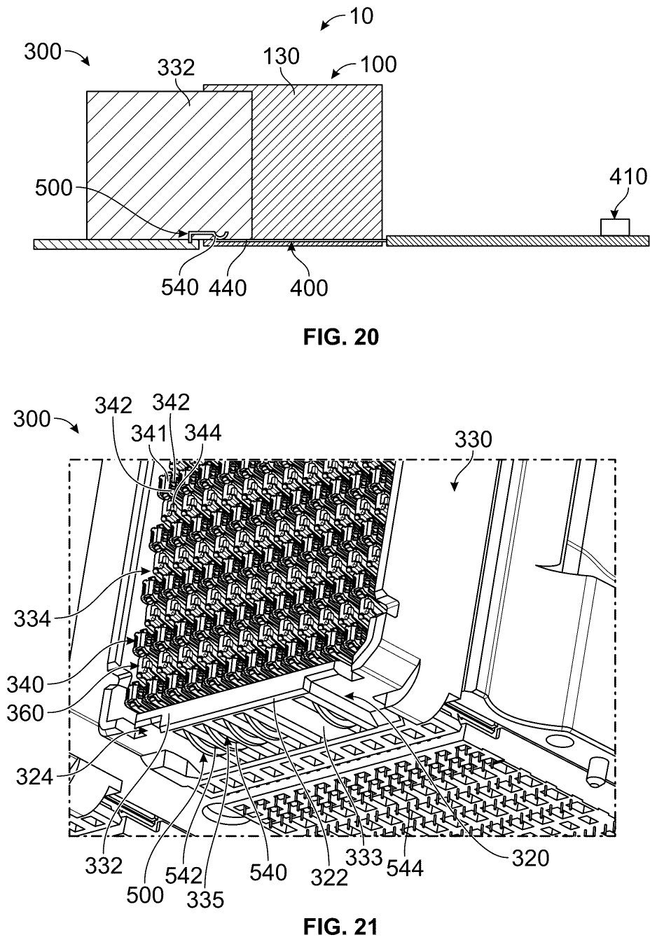

FIG. 20 is a partial sectional view of a portion of the communication system 10 showing the circuit card connector assembly 300 mated with the cable connector assembly 100 showing the circuit card connector identification module 500 mated with the cable connector identification module 400 in accordance with an exemplary embodiment.

In the illustrated embodiment, the circuit card connector identification module 500 includes the identification contacts 540 at the bottom of the connector housing 332 to connect to the cable connector identification module 400 when the connector assemblies 100, 300 are connected. The cable connector identification module 400 includes the identification contacts 440 at the bottom of the connector housing 132 to interface with the identification contacts 540. The identification contacts 440 are routed to the rear of the cable connector 130 and are configured to be electrically connected to the identification device 410, such as via a dongle or cable connection. However, the identification device 410 may be coupled to the connector housing 132 rather than being connected by a dongle in alternative embodiments.

FIG. 21 is a bottom perspective view of a portion of the circuit card connector assembly 300 showing the circuit card connector identification module 500 in accordance with an exemplary embodiment. The circuit card connector assembly 300 includes the board connector(s) 330 configured to mounted to the circuit card 310 (FIG. 14). The board connectors 330 are held in the board connector housing 332 and include the communication contact modules 360 configured to transmit data, such as high speed data signals. The communication contact modules 360 are arranged in the cavity 334 in a contact module stack.

Each contact module 360 includes a structure holding contact assemblies 340. Each contact assembly 340 includes at least one signal contact 342, a contact holder 341 holding the at least one signal contact 342, and a shield 344 coupled to the contact holder 341 and providing electrical shielding for the at least one signal contact 342. Optionally, multiple contact assemblies 340 may be integrated into a common structure. For example, the contact holders 341 of each of the contact assemblies 340 may be a unitary structure, such as being a single molded piece holding all of the signal contacts 342 and the shields 344.

In the illustrated embodiment, each contact assembly 340 includes a pair of the signal contacts 342, which define a differential pair. In various embodiments, the signal contacts 342 may be deflectable spring beams at mating ends. However, in alternative embodiments, the signal contacts 342 may be pin contacts, socket contacts, or other types of contacts. The signal contacts 342 may be stamped and formed contacts. Each signal contact 342 is configured to be electrically connected to the circuit card 310. For example, terminating ends of the signal contacts 342 may include compliant pins or solder tails configured to be connected to the circuit card 310.

The shield 344 may be a stamped and formed shield. The shield 344 is configured to be coupled to the contact holder 341. Optionally, shields may be provided at both sides of the contact module 360. The shield 344 may provide shielding on multiple sides of the signal contacts 342. In an exemplary embodiment, the front end of the shield 344 is C-shaped providing electrical shielding on three sides of the pair of signal contacts 342. The shield 344 may have other shapes in alternative embodiments. The shield 344 may have deflectable spring beams configured to be mated to a shield structure of the circuit card connector assembly 300. The shield 344 may be configured to be electrically connected to the cable shield of the cable.

The connector housing 332 defines a mating end configured to be mated with the cable connector 130. For example, the mating end may be plugged into a receptacle of the cable connector 130 and/or a portion of the connector housing 332 may define a receptacle that receives a portion of the cable connector 130. In an exemplary embodiment, the walls 333 of the connector housing 332 define portions of the guide module 320. For example, the walls 333 may include lead-in surfaces 322 and cutouts, slots, or guide slots 324 defining guide features to guide mating with the cable connector 130. The circuit card connector identification module 500 may be incorporated into the connector housing 332, such as at the walls 333 (for example, at the guide slots 324 or at guide surface along the walls 333). In the illustrated embodiment, the circuit card connector identification module 500 is incorporated into the bottom wall of the walls. Other locations are possible in alternative embodiments. The circuit card connector identification module 500 may be located at the exterior surfaces of the wall(s) 333 (for example, at the bottom surface).

In an exemplary embodiment, the connector housing 332 includes contact channels 335 that receive the identification contacts 540. The contact channels 335 are located in the bottom wall in the illustrated embodiment. Other locations are possible in alternative embodiments. The identification contacts 540 include spring beams, such as deflectable spring beams, at the mating ends 542 configured to interface with the identification contacts 440. The mating ends 542 extend below the bottom surface of the bottom wall to interface with the identification contacts 440 when mated with the cable connector 130. The terminating ends 544 of the identification contacts 540 are located at the board interface, such as at the bottom of the board connector 330, to interface with the circuit card.

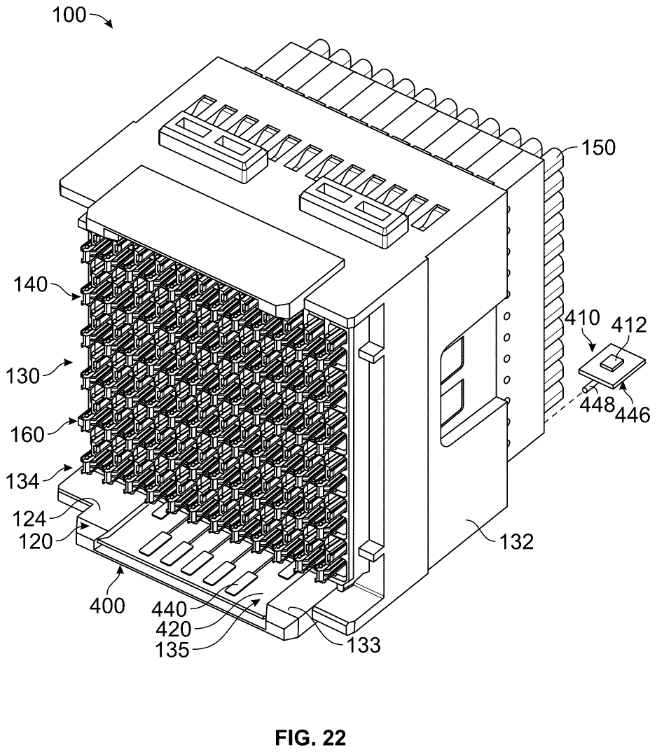

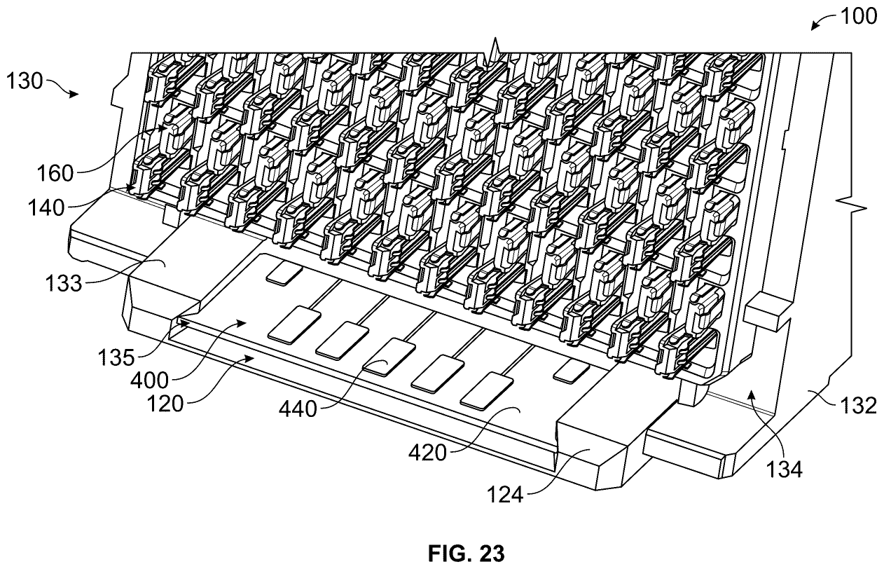

FIG. 22 is a front perspective view of a portion of the cable connector assembly 100 in accordance with an exemplary embodiment showing one of the cable connectors 130. FIG. 23 is an enlarged view of a portion of the cable connector 130 shown in FIG. 22. FIGS. 22 and 23 illustrate the cable connector identification module 400 at an exemplary location, such as along a portion of the guide module 120, such as along a guide feature or guide surface of the connector housing 132 used to guide mating with the circuit card connector assembly 300. In the illustrated embodiment, the cable connector identification module 400 includes the identification contacts 440 at the bottom of the connector housing 132 to interface with the identification contacts 540. The identification contacts 440 are routed to the rear of the cable connector 130 and are configured to be electrically connected to the identification device 410, such as via a dongle or cable connection. For example, the cable connector identification module 400 includes the remote identification device 446, such as a dongle, connected to the printed circuit board 420 via cables 448. The electronic device 412 is part of the remote identification device 446. However, the identification device 410 and the electronic device 412 may be incorporated into the connector housing 132, such as being coupled to the connector housing 132 or mounted directly to the printed circuit board 420 rather than being connected by a dongle in alternative embodiments.

The cable connector 130 includes the connector housing 132 holding the communication contact modules 160 configured to transmit data, such as high speed data signals. The contact modules 160 include the contact assemblies 140 configured to be mated with the circuit card connector assembly 300. The contact assemblies 140 are terminated to the ends of the cables 150 extending from the cable connector 130.

The connector housing 132 defines the mating end configured to be mated with the board connector 330. For example, the mating end may be plugged into a receptacle of the board connector 330 and/or a portion of the connector housing 132 may define a receptacle that receives a portion of the board connector 330. In an exemplary embodiment, the walls 133 of the connector housing 132 define portions of the guide module 120. For example, the walls 133 may include lead-in surfaces 122 and the guide rails 124 defining guide features to guide mating with the board connector 330. The cable connector identification module 400 may be incorporated into the connector housing 132, such as at the walls 133 (for example, at the guide rails 124 or at a guide surface along the walls 133). In the illustrated embodiment, the cable connector identification module 400 is incorporated into the bottom wall of the walls 133. Other locations are possible in alternative embodiments. The cable connector identification module 400 may be located at the interior surfaces of the wall(s) 133 (for example, at the bottom wall). In an exemplary embodiment, the walls 133 include a pocket 135 that receives the printed circuit board 420 of the cable connector identification module 400. The printed circuit board 420 is exposed in the pocket 135 for interfacing with the circuit card connector identification module 500. For example, the identification contacts 440 of the cable connector identification module 400 may be exposed within the pocket 135 for mating with the circuit card connector identification module 500.

The walls 133 of the connector housing 132 may be chamfered to guide mating of the board connector 330 in the cavity 134. The lead-in surfaces and/or walls of the connector housing 132 may form a guide module for the cable connector assembly 100. The connector housing 132 may have guide features to properly position the board connector 330 within the cavity 134 and/or to properly position a plug portion at the mating end of the connector housing 132 in the board connector 330. The connector housing 132 may include guide lugs or guide rails 124 at the mating interface to guide mating and/or for keyed mating with the board connector 330. The guide rails 124 may form surfaces for locating components of the cable connector identification module 400. For example, the circuits, contacts, or conductors of the cable connector identification module 400 may be located along the top surfaces, bottom surfaces, side surfaces, and the like of the guide rails 124.

In the illustrated embodiment, the cable connector identification module 400 is integrated into the guide module 120. For example, the cable connector identification module 400 is integrated into the guide walls of the connector housing 132 used to guide mating with the board connector 330. As such, the cable connector identification module 400 does not occupy any additional space or real estate within the cable connector assembly 100 and does not require the cable connector assembly 100 to dimensionally expand either vertically or horizontally. Additionally, the cable connector identification module 400 does not use any of the data channels of the cable connector 130 to transmit the identification data, thus allowing all of the data channels for high speed data communication between the cable connector 130 and the corresponding board connector 330.

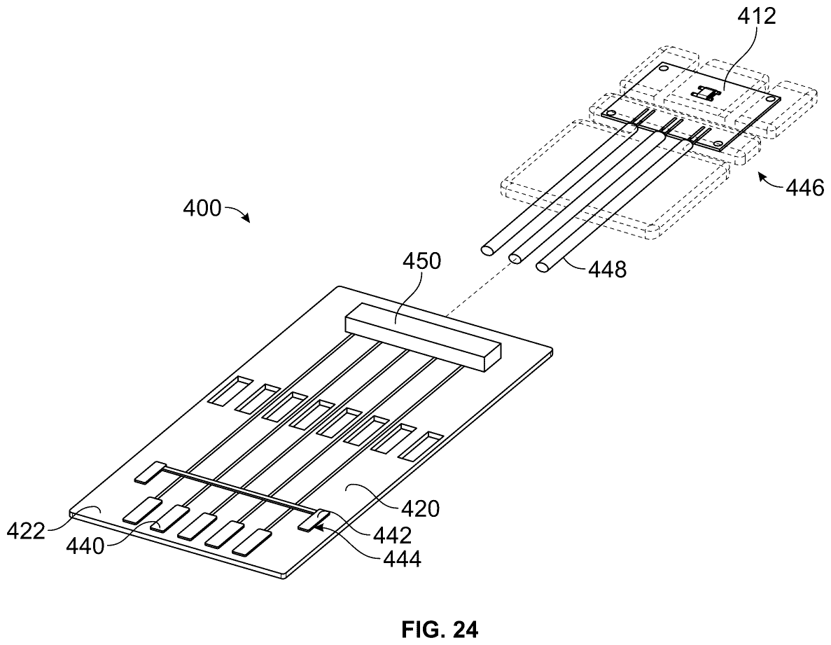

FIG. 24 is a perspective view of the cable connector identification module 400 in accordance with an exemplary embodiment. In an exemplary embodiment, the cable connector identification module 400 includes the identification device 410 and identification contacts 440 operably coupled to the identification device 410. The identification contacts 440 may be signal contacts, power contacts, ground contacts, loopback contacts, proximity contacts, or other types of contacts. The identification contacts 440 are configured to be mated with the circuit card connector identification module 500 to electrically connect the cable connector identification module 400 and the circuit card connector identification module 500.

In an exemplary embodiment, the identification device 410 includes the electronic device 412 that stores unique identification data. In the illustrated embodiment, the identification device includes the remote identification device 446 having the electronic device 412 separate from the printed circuit board 420 and coupled to the printed circuit board 420, such as via the cables 448. The cables 448 may be directly terminated to the printed circuit board 420, such as being soldered to conductors or pads on the printed circuit board 420. Alternatively, as in the illustrated embodiment, the identification device 410 includes a connector 450 allowing connection of the remote identification device 446 to the printed circuit board 420. The connector 450 may be a card edge connector configured to receive an end of a circuit card or may be another type of connector. In other alternative embodiments, rather than using the remote identification device 446, the electronic device 412 may be terminated directly to the printed circuit board 420, such as being soldered to circuits on the printed circuit board 420.

In an exemplary embodiment, the electronic device 412 is an EEPROM device, such as an EEPROM chip or component. The electronic device 412 is programmable to store the identification data, such as a part number, a program name, a slot ID number, and the like. The electronic device 412 may be a surface mount component, such as having solder tails, solder pads, solder balls, or other conductors or leads for connection to another component, such as a circuit board or directly to the identification contacts 440.

In an exemplary embodiment, the printed circuit board 420 includes circuits, such as pads, traces, vias, and the like. The circuits may define the identification contacts 440. In alternative embodiments, the identification contacts 440 may be separate contacts, such as stamped and formed contacts, terminated to the printed circuit board 420 and extending from the printed circuit board 420 for mating with the circuit card connector identification module 500. In the illustrated embodiment, the identification contacts 440 are pads of the printed circuit board 420 arranged at the card edge 422 of the printed circuit board 420. The card edge 422 is provided at a mating end of the identification device 410 for mating with the circuit card connector identification module 500. For example, the card edge 422 may be plugged into a card slot of the circuit card connector identification module 500.

In the illustrated embodiment, the cable connector identification module 400 includes the loopback contacts 442 forming the loopback circuit 444. The loopback contacts 442 are configured to be coupled to corresponding loopback contacts of the circuit card connector identification module 500. The loopback circuit 444 provides indication to the connector identification system 40 that the connectors are properly mated. The feedback provided by the loopback circuit 444 may control operation of the system, such as to power up or power down and/or to transmit signals based on the loopback circuit 444 being closed or open. In an exemplary embodiment, the loopback contacts 442 are offset relative to the other identification contacts 440, such as further from the mating edge to allow last mate/first break to provide indication of full mating of the connectors, such as to control on/off of the data and/or power transmissions.

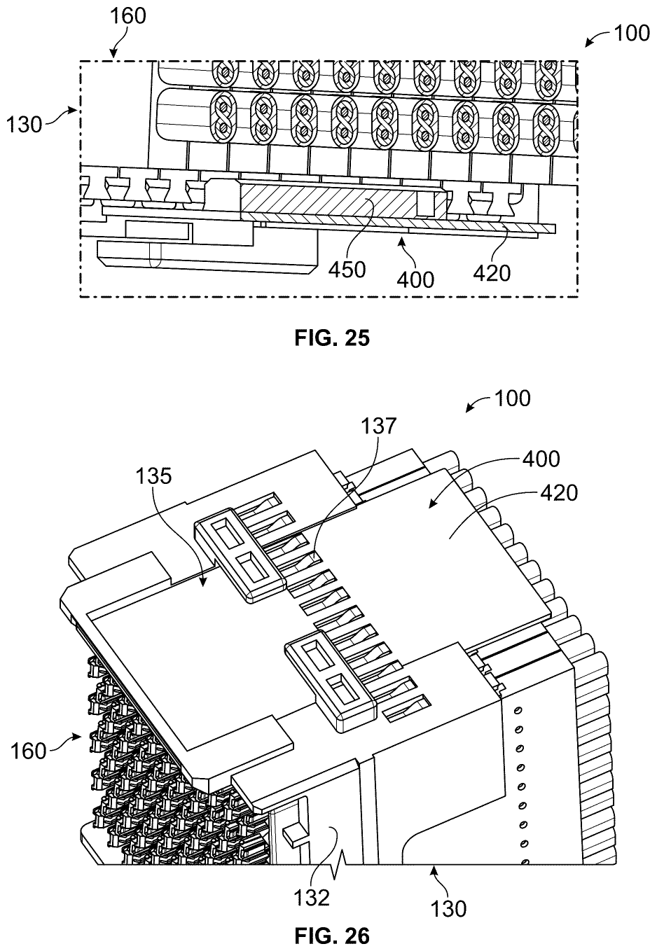

FIG. 25 is a rear perspective view of the cable connector assembly 100 in accordance with an exemplary embodiment showing the cable connector identification module 400 coupled to the cable connector 130. The connector 450 is shown at the rear of the cable connector 130, which is used for connection of the remote identification device 446. The cable connector identification module 400 is located below the communication contact modules 160 and does not interfere with the positioning of the communication contact modules 160. The cable connector identification module 400 does not occupy space otherwise dedicated to the communication contact modules 160 and thus does not affect the number of data lines through the cable connector 130.

FIG. 26 is a bottom perspective view of the cable connector assembly 100 in accordance with an exemplary embodiment showing the cable connector identification module 400 coupled to the cable connector 130. The printed circuit board 420 is located at the bottom of the connector housing 132. The printed circuit board 420 is received in the pocket 135 in the bottom wall and held in the bottom wall, such as using latches 137. The cable connector identification module 400 is located below the communication contact modules 160 and does not interfere with the positioning of the communication contact modules 160. The cable connector identification module 400 does not occupy space otherwise dedicated to the communication contact modules 160 and thus does not affect the number of data lines through the cable connector 130.

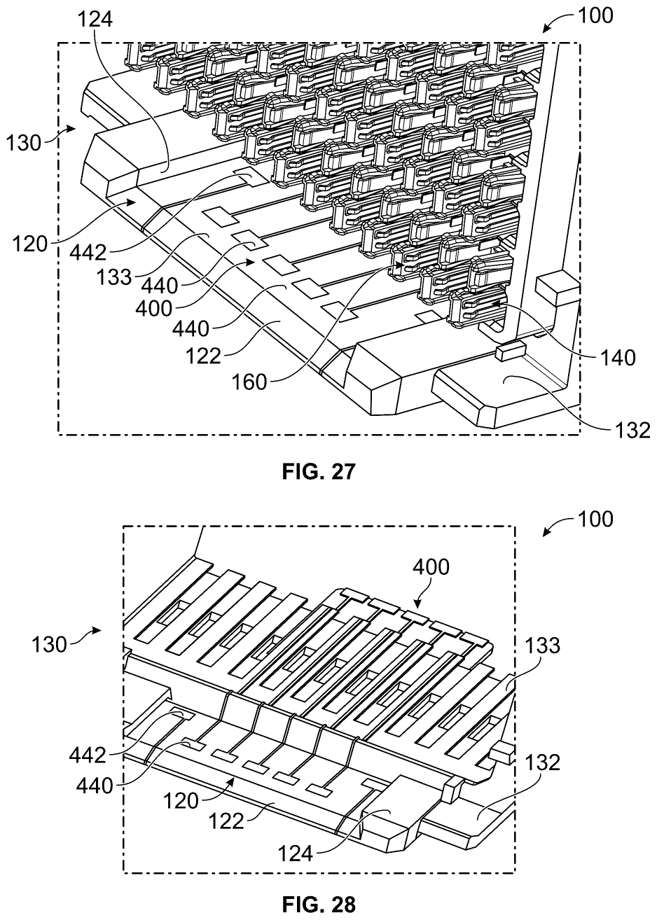

FIG. 27 is a perspective view of the cable connector assembly 100 in accordance with an exemplary embodiment showing the cable connector identification module 400 coupled to the cable connector 130. FIG. 28 is a bottom perspective view of a portion of the cable connector 130 showing the cable connector identification module 400 on the connector housing 132. FIGS. 27 and 28 illustrate the cable connector identification module 400 at an exemplary location, such as along a portion of the guide module 120, such as along a guide feature or guide surface of the connector housing 132 used to guide mating with the circuit card connector assembly 300.

The cable connector 130 includes the connector housing 132 holding the communication contact modules 160 configured to transmit data, such as high speed data signals. The contact modules 160 include the contact assemblies 140 configured to be mated with the circuit card connector assembly 300. The contact assemblies 140 are terminated to the ends of the cables 150 extending from the cable connector 130.

The connector housing 132 defines the mating end configured to be mated with the board connector 330. For example, the mating end may be plugged into a receptacle of the board connector 330 and/or a portion of the connector housing 132 may define a receptacle that receives a portion of the board connector 330. In an exemplary embodiment, the walls 133 of the connector housing 132 define portions of the guide module 120. For example, the walls 133 may include the lead-in surfaces 122 and the guide rails 124 defining guide features to guide mating with the board connector 330. The cable connector identification module 400 may be incorporated into the connector housing 132, such as at the walls 133 (for example, at the guide rails 124 or at a guide surface along the walls 133). In the illustrated embodiment, the cable connector identification module 400 is incorporated into the bottom wall of the walls 133. Other locations are possible in alternative embodiments. The cable connector identification module 400 may be located at the interior surfaces of the wall(s) 133 (for example, at the bottom wall).

In the illustrated embodiment, the cable connector identification module 400 includes the identification contacts 440 at the bottom of the connector housing 132 to interface with the identification contacts 540. The identification contacts 440 are routed to the rear of the cable connector 130 and are configured to be electrically connected to the identification device 410, such as via a dongle or cable connection or by a direct connection via soldering of the electronic device 412 to the circuits.

In an exemplary embodiment, the identification contacts 440 are formed directly on the bottom wall. For example, the bottom wall forms a substrate for supporting the identification contacts 440. The identification contacts 440 may be formed by laser direct structuring (LDS) the circuits directly onto the walls 133. The identification contacts 440 may be formed by other processes, such as plating, on the walls 133. The identification contacts 440 are routed along the wall 133, such as from the front to the rear. The identification contacts 440 include mating pads at the front configured for mating with the identification contacts 540 of the circuit card connector identification module 500. The identification contacts 440 include rear pads at the rear configured for receiving the cables 448 of the EEPROM dongle or the connector 450 or the electronic device 412. Forming the identification contacts 440 directly on the wall 133 eliminates the need for the separate printed circuit board 420.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A communication system comprising:
a cable connector assembly including a cable connector and cables extending from the cable connector, the cable connector including a cable connector housing having walls defining a cavity, the cable connector including cable contact assemblies received in the cavity, each cable contact assembly including a cable contact holder holding a first signal contact and a first shield providing shielding for the first signal contact, the first signal contacts and the first shields of the cable contact assemblies arranged at a mating end of the cable connector, the cables terminated to the first signal contacts and extending from a cable end of the cable connector, the cables defining data channels, the cable connector assembly including a cable connector identification module including first identification contacts and an identification device having unique identification data stored on the identification device; and
a circuit card connector assembly including a circuit card and a board connector mounted to the circuit card, the board connector including a board connector housing having walls defining a receptacle, the board connector including board contact assemblies held by the board connector housing, the board contact assemblies including second signal contacts and second shields providing shielding for the second signal contact, the second signal contacts and the second shields arranged at a mating end of the board connector for mating with the corresponding first signal contacts and the first shields, the second signal contacts and the second shields being terminated to the circuit card, the circuit card connector assembly including a circuit card connector identification module including second identification contacts configured to be mated with the first identification contacts;
wherein the first identification contacts are coupled to the second identification contacts to transmit the unique identification data from the identification device to the circuit card connector assembly.

2. The communication system of claim 1, wherein the cable connector assembly includes a cable connector guide module, the circuit card connector assembly including a circuit card connector guide module, the cable connector guide module interfacing with the circuit card connector guide module to pre-align the cable connector with the board connector prior to mating engagement of the first signal contacts with the second signal contacts, the cable connector identification module integrated with the cable connector guide module, the circuit card connector identification module integrated with the circuit card connector guide module.

3. The communication system of claim 1, wherein the second identification contacts are stamped and formed contacts each extending between a mating end and a terminating end, the terminating end being terminated to the circuit card, the mating end configured to be mated to the first identification contacts of the cable connector identification module at a separable mating interface.

4. The communication system of claim 1, wherein the second identification contacts are held by the board connector housing and are exposed at an interior surface of at least one of the walls of the board connector housing to interface with the cable connector assembly.

5. The communication system of claim 1, wherein the circuit card connector identification module includes a contact holder holding the second identification contacts, the contact holder being received in a pocket in the board connector housing to position the second identification contacts between the mating end and the circuit card.

6. The communication system of claim 1, further comprising a cable connector guide module, the cable connector guide module configured to interface with a circuit card connector guide module of the circuit card connector assembly to pre-align the cable connector with the circuit card connector assembly prior to mating engagement of the first and second signal contacts, the cable connector identification module integrated with the cable connector guide module.

7. The communication system of claim 6, wherein the cable connector guide module includes a guide blade protruding forward of the cable connector housing and configured to plug into a guide slot of the circuit card connector assembly, the guide blade having a lead-in surface to guide mating with the guide slot, the identification contacts exposed along a first surface of the guide blade to interface with the cable card connector interface module when received in the guide slot.

8. The communication system of claim 6, wherein the cable connector guide module includes a lead-in surface forward of the signal contacts, the identification contacts located along the lead-in surface.

9. The communication system of claim 6, wherein the cable connector guide module is provided on one or more of the walls of the cable connector housing.

10. The communication system of claim 1, wherein the cable connector identification module includes a printed circuit board having a card edge, the identification contacts being circuits of the printed circuit board at the card edge, the card edge exposed at the mating end for mating with the circuit card connector identification module.

11. The communication system of claim 10, wherein the identification device is mounted to the circuit board.

12. The communication system of claim 10, wherein the cable connector identification module includes an identification connector mounted to the circuit board, the identification device configured to be mated to the identification connector at a separable mating interface.

13. The communication system of claim 1, wherein the identification contacts are circuits formed on the cable connector housing.

14. The communication system of claim 1, wherein the cable connector identification module includes a loopback circuit to detect mating of the cable connector with the circuit card connector assembly.

15. The communication system of claim 1, wherein the cable connector assembly includes a connector holder having a frame defining a connector chamber, the frame extending between a front and a rear of the connector holder, the frame including an upper frame member, a lower frame member, and first and second side frame members extending between the upper and lower frame members to define the connector chamber, the connector holder configured to be mounted to a panel, the cable connector received in the connector chamber with the mating end of the cable connector extending forward from the front of the frame and configured to pass through an opening in the panel for mating with the circuit card connector assembly.

16. The communication system of claim 15, wherein the cable connector identification module is held by the frame adjacent the cable connector.

17. The communication system of claim 1, wherein the cable connector identification module includes an identification cable between the identification contacts and the identification device.

18. The communication system of claim 1, wherein the cable connector identification module includes a printed circuit board, the identification contacts being provided on at least one surface of the printed circuit board, the identification device being electrically connected to the identification contacts through the printed circuit board.

19. The communication system of claim 1, wherein the identification device is an EEPROM device.

20. A cable connector assembly comprising:
a cable connector including a cable connector housing having walls defining a cavity, the cable connector including cable contact assemblies received in the cavity, each cable contact assembly including a contact holder holding a signal contact and a shield providing shielding for the signal contact, the signal contacts and the shields of the cable contact assemblies arranged at a mating end of the cable connector configured to be mated with a circuit card connector assembly;
cables terminated to the signal contacts and extending from a cable end of the cable connector, the cables defining data channels; and
a cable connector identification module configured to be mated with the circuit card connector assembly, the cable connector identification module including identification contacts and an identification device having unique identification data stored on the identification device, the identification device being operably coupled to the identification contacts to transmit the unique identification data to the circuit card connector assembly.

21. A circuit card connector assembly comprising:
a circuit card including a substrate having a mounting surface, the circuit card including circuit contacts at the mounting surface;
a board connector mounted to the circuit card at the mounting surface, the board connector including a board connector housing having walls defining a receptacle, the board connector including board contact assemblies held by the board connector housing, the board contact assemblies including signal contacts and shields providing shielding for the signal contact, the signal contacts and the shields arranged at a mating end of the board connector for mating with a cable connector assembly, the signal contacts and the shields being terminated to the circuit contacts of the circuit card; and
a circuit card connector identification module including identification contacts configured to be mated with a cable connector identification module of the cable connector assembly, wherein the identification contacts are configured to receive unique identification data from the cable connector identification module.
